(19) United States
(12) Patent Application Publication
(10) Pub. No.: US 2025/0038687 A1
(43) Pub. Date: Jan. 30, 2025

(54) APPARATUS FOR AND METHOD OF OPTIMIZING PARAMETER OF NOTCH FILTER FOR USE IN ELECTRIC POWER STEERING APPARATUS

(71) Applicant: HYUNDAI MOBIS CO., LTD., Seoul (KR)

(72) Inventors: Di Do CHOI, Yongin-si (KR); Jae Min KUK, Yongin-si (KR)

(73) Assignee: HYUNDAI MOBIS CO., LTD., Seoul (KR)

(21) Appl. No.: 18/765,709

(22) Filed: Jul. 8, 2024

(30) Foreign Application Priority Data
Jul. 24, 2023 (KR) 10-2023-0096228

(51) Int. Cl. H02P 23/12; B62D 5/04; H03H 17/02

(52) U.S. Cl. CPC H02P 23/12; B62D 5/0463; H03H 17/025

(57) ABSTRACT

Proposed are an apparatus for and a method of optimizing a parameter of a notch filter for use in an electric power steering apparatus to eliminate noise and vibration occurring in the electric power steering apparatus. The apparatus includes: a communication interface, and a processor operatively connected to the communication interface, wherein the processor receives through the communication interface a torque signal from a torque sensor detecting column torque resulting from rotation of a steering wheel, detects an optimal value for a notch depth of the notch filter that minimizes a function value of an objective function that is defined as a mean squared error between the torque signal and a preset target torque signal of the notch filter, and applies the optimal value to the notch filter.

### CROSS-REFERENCE TO RELATED APPLICATION

This application claims priority from and the benefit of Korean Patent Application Mo. 10-2023-0096228, filed on Jul. 24, 2023, which is hereby incorporated by reference for all purposes as if set forth herein.

### BACKGROUND

### Field

Exemplary embodiments relate to an apparatus for and a method of optimizing a parameter of a notch filter for use in an electric power steering apparatus.

### Discussion of the Background

Steering apparatuses, each having a steering wheel, include an electric power steering (EPS) apparatus assisting a driver in readily operating the steering wheel. The electric power steering apparatus, including a drive motor, assists the driver in operating the steering wheel even with less force. This electric power steering apparatus, when in operation, generates noise and vibration due to its mechanical characteristics. A variable notch filter is used in the electric power steering apparatus in order to reduce noise and vibration occurring by the electric power steering apparatus.

Characteristics of the noise and vibration occurring by the electric power steering apparatus may vary according to vehicle models. Therefore, there is a need to set a parameter of the variable notch filter in a manner that varies with a vehicle model. Accordingly, it takes substantial effort and time to optimize the parameter of the variable notch filter.

The related art of the present disclosure is disclosed in Korean Patent Application Publication No. 10-2023-0008411 (published on Jan. 16, 2023).

### SUMMARY

Various embodiments of the present disclosure are directed to an apparatus for and a method of optimizing a parameter of a notch filter in use for an electric power steering apparatus, the apparatus and the method being capable of facilitating optimization of a notch filter in use for the electric power steering apparatus.

In an embodiment, according to an aspect of the present disclosure, an apparatus for optimizing a parameter of a notch filter for use in an electric power steering apparatus includes: a communication interface; and a processor operatively connected to the communication interface, wherein the processor receives through the communication interface a torque signal from a torque sensor detecting column torque resulting from rotation of a steering wheel, detects an optimal value for a notch depth of the notch filter that minimizes a function value of an objective function that is defined as a mean squared error between the torque signal and a preset target torque signal of the notch filter, and applies the optimal value to the notch filter.

In an embodiment, in the apparatus, the processor may detect the optimal value for the notch depth by executing a steepest gradient descent algorithm with respect to the objective function.

In an embodiment, in the apparatus, the processor may detect the optimal value for the notch depth by reiterating a process of updating the notch depth using Mathematical Equation that follows, until the notch depth converges:

$${γ}_{k + 1} = {γ}_{k} + 2 μ \frac{( 1 - {γ}_{k} ) {ζ}_{w} α s}{{s}^{2} + {ζ}_{w} α s + {α}^{2}} \frac{{ζ}_{w} α s}{{s}^{2} + {ζ}_{w} α s + {α}^{2}} {τ}_{ref}^{2}$$

where γ depicts

$$\frac{2}{\frac{1}{β} + β} ,$$

β depicts a notch depth, u depicts a step size of a steepest gradient descent algorithm, ζ_{w} depicts a notch width (bandwidth), α depicts the order of noise and vibration (the order of a noise frequency), s depicts a Laplace complex variable, and τ_{ref} depicts a torque signal.

In an embodiment, in the apparatus, the processor may determine whether or not the notch depth is possibly optimized, and when the notch depth is determined to be optimized, the processor may detect the optimal value.

In an embodiment, in the apparatus, the processor may receive information on a steering speed of the steering wheel through the communication interface, and, when the steering speed reaches or exceeds a preset reference speed, the processor may determine that the notch depth is possibly optimized.

In an embodiment, in the apparatus, the processor may filter the torque signal using a band pass filter, may convert the filtered torque signal into a torque signal having absolute values, may filter the torque signal having the absolute values, using a low pass filter, and thus may pre-process the torque signal.

In an embodiment, in the apparatus, in a case where the notch filter is a secondary notch filter of which an input is an output of a different notch filter, the processor may detect the optimal value for the notch depth of the notch filter using an objective function that is defined a mean squared error between an output signal of the different notch filter and the preset target torque signal, and may apply the optimal value to the notch filter.

In an embodiment, a method of optimizing a parameter of a notch filter for use in electric power steering apparatus to eliminate noise and vibration occurring in the electric power steering apparatus according to another aspect of the present disclosure, includes receiving through the communication interface a torque signal from a torque sensor detecting column torque resulting from rotation of a steering wheel; detecting an optimal value for a notch depth of the notch filter that minimizes a function value of an objective function that is defined as a mean squared error between the torque signal and a preset target torque signal of the notch filter; and applying the optimal value to the notch filter.

According to the present disclosure, a parameter of the notch filter for use in the electric power steering apparatus is in real time optimized based on the column torque resulting from the rotation of the steering wheel. Thus, noise, vibration, and harshness (NVH) characteristics of the electric power steering apparatus can be improved.

According to the present disclosure, the time taken to optimize the parameter of the notch filter for use in the electric power steering apparatus can be shortened.

The present disclosure is not limited to the above-mentioned effects. From the following description, an additional effect of the present disclosure would be apparent to a person of ordinary skill in the art.

### BRIEF DESCRIPTION OF THE DRAWINGS

FIG. 1 is a block diagram illustrating an apparatus for optimizing a parameter of a notch filter for use in an electric power steering apparatus according to a first embodiment of the present disclosure.

FIG. 2 is a flowchart illustrating a method of optimizing a parameter of a notch filter for use in the electric power steering apparatus according to a second embodiment of the present disclosure.

FIG. 3 is a graph showing the results of performing pre-processing on a torque signal according to the second embodiment of the present disclosure.

FIG. 4 is a flowchart illustrating a method of optimizing a parameter of a notch filter for use in the electronic steering apparatus according to a third embodiment of the present disclosure.

FIG. 5A is a view illustrating a column-electric power steering (C-EPS) apparatus. FIG. 5B is a graph showing the results of analyzing noise and vibration of the column-electric power steering apparatus.

FIG. 6A a view illustrating a rack-electric power steering (R-EPS) apparatus. FIG. 6B is a graph showing the results of analyzing noise and vibration of the rack-electric power steering apparatus.

FIG. 7 is a graph showing the performance of the apparatus for optimizing a parameter of a notch filter for use in the electric power steering apparatus according to the first embodiment of the present disclosure.

### DETAILED DESCRIPTION OF THE ILLUSTRATED EMBODIMENTS

An apparatus 100 for and methods of optimizing a parameter of a notch filter for use in an electric power steering apparatus according to a first, second, and third embodiments, respectively, of the present disclosure will be described in detail below with reference to the accompanying drawings. For clarity and convenience in description, thicknesses of lines, sizes of constituent elements, and the like may be illustrated in a non-exact proportion in the drawings. In addition, terms defined by considering their respective meanings in the present disclosure will be used below and may vary according to the user's or manager's intention or according to practices in the art. Therefore, these terms should be contextually defined in light of the present specification.

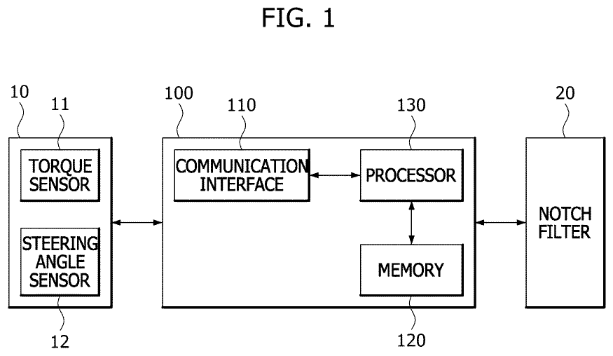

FIG. 1 is a block diagram illustrating the apparatus 100 for optimizing a parameter of a notch filter for use in the electric power steering apparatus according to the first embodiment of the present disclosure.

With reference to FIG. 1, the apparatus 100 for optimizing a parameter of a notch filter (hereinafter referred to as a parameter optimization apparatus) for use in the electric power steering apparatus according to the first embodiment of the present disclosure may include a communication interface 110, a memory 120, and a processor 130. Constituents that are included in the parameter optimization apparatus 100 according to the present disclosure may be connected to each other through a shared bus and may be connected to each other through individual interfaces or individual buses, with the processor 130 in between. The parameter optimization apparatus 100 according to the first embodiment of the present disclosure may further include various constituent elements in addition to constituent elements illustrated in FIG. 1 or may omit one or several constituent elements from among the above-mentioned constituent elements.

The communication interface 110 may communicate with an external device 10. For example, the communication interface 110 may communicate with a torque sensor 11 that detects column torque resulting from rotation of a steering wheel, thereby receiving a torque signal from the torque sensor 11. In addition, the communication interface 110 may communicate with a steering angle sensor 12 that detects a steering speed resulting from the rotation of the steering wheel and may receive information on a steering speed (the steering angle speed) from the steering angle sensor 12. The communication interface 110 may communicate with the external device 10 in compliance with various types of communication schemes.

Various types of information required while the processor 130 operates may be stored in the memory 120. In addition, various types of information generated while the processor 130 operates may be stored in the memory 120.

The processor 130 may be operatively connected to the communication interface 110 and the memory 120. The processor 130 may also be implemented as a central processing unit (CPU), a micro-controller unit (MCU), or a system-on-chip (SoC). The processor 130 may be configured to control a plurality of hardware or software constituent elements connected to the processor 130 by executing an operating system or an application, to perform various data processing and computation operations, to execute at least one command stored in the memory 120, and to store the execution-resulting data in the memory 120.

The processor 130 may receive the torque signal from the torque sensor 11 through the communication interface 110 and may detect an optimal value for the notch depth of the notch filter 20 that minimizes a function value of an objective function that is defined as a mean squared error between the received torque signal and a preset target torque signal of the notch filter 20. Then, the processor 130 may optimize the notch filter 20 by applying the detected optimal value to the notch filter 20. The target torque signal here may refer to a final torque signal that is desired to be obtained by filtering the torque signal through the notch filter 20. This torque target signal may be set by a user. The notch depth may be defined as a parameter that determines the extent of attenuation of the notch filter 20. The processor 130 may detect the notch depth of the notch filter 20 that minimizes a difference between the torque signal and the target torque signal and may determine the detected notch depth as an optimal notch depth.

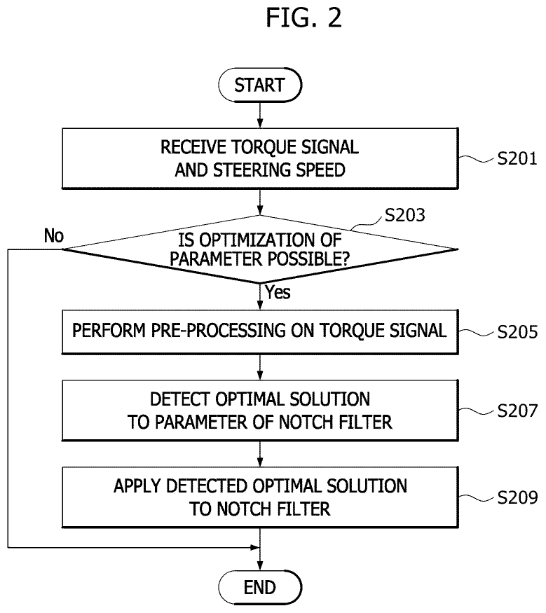

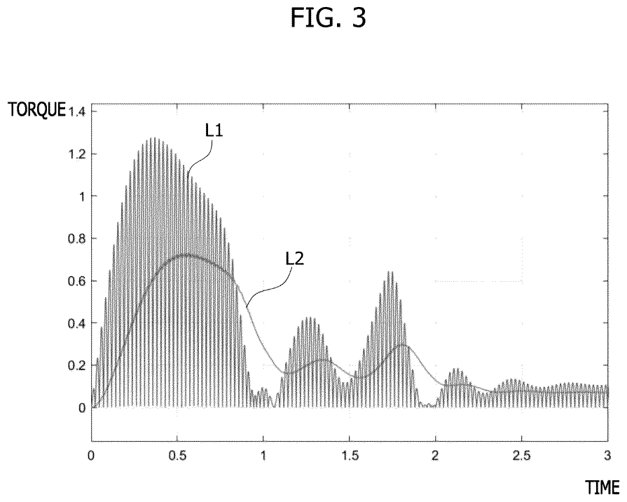

FIG. 2 is a flowchart illustrating a method of optimizing a parameter of a notch filter for use in the electric power steering apparatus according to a second embodiment of the present disclosure. FIG. 3 is a graph showing the results of performing pre-processing on the torque signal according to the second embodiment of the present disclosure.

Steps of optimizing a parameter of the notch filter 20 that the processor 130 applies to the electric power steering apparatus are described below with reference to FIG. 2. One or several of the steps described below may be performed in a different order from the one described below or may be omitted.

First, the processor 130 may receive information on the torque signal and on the steering speed for the steering wheel through the communication interface 110 (S201). Specifically, the processor 130 may receive the information on the torque signal from the torque sensor 11. In addition, the processor 130 may receive the information on the steering speed from the steering angle sensor 12.

Subsequently, the processor 130 may determine, based on the information on the steering speed, whether or not the parameter of the notch filter 20 is possibly optimized (S203). When the steering speed of the steering wheel reaches or exceeds a preset reference speed (for example, 0.5 RPS), the processor 130 may determine that the parameter of the notch filter 20 is possibly optimized. The reference speed may be set, taking into consideration factors, such as a step size and characteristics of the notch filter 20, that are used when executing a steepest gradient descent algorithm.

In the second embodiment, the parameter (the notch depth) of the notch filter 20 is optimized using the steepest gradient descent algorithm. However, when the steering speed of the steering wheel does not reach a predetermined value, the divergence of a parameter value may occur while finding an optimal value of the parameter of the notch filter 20. In this case, a problem arises in that the optimal value of the parameter is difficult to find. Therefore, in the second embodiment, in order to prevent this problem from occurring, the optimization of the parameter of the notch filter 20 proceeds only when the steering speed of the steering wheel reaches or exceeds the predetermined value.

When it is determined that the parameter of the notch filter 20 is possibly optimized, the processor 130 may perform pre-processing on the torque signal received through the communication interface 110 (S205). In Step S205, the processor 130 may filter the torque signal received through the communication interface 110 using a band pass filter (BPF), may convert the filtered torque signal into a torque signal having absolute values, and may filter the torque signal having the absolute values, using a low pass filter (LPF). The processor 130 may extract only a torque signal corresponding to the order at which noise and vibration occur, using the band pass filter. In addition, the processor 130 may convert the filtered torque signal into a torque signal having absolute values in order to quantify a magnitude of the torque signal. In addition, the processor 130 may eliminate unnecessary noise contained in the torque signal, using the low pass filter. When the torque signal is converted into a torque signal having absolute values, the torque signal having the absolute values is shown as indicated by L1 in FIG. 3. Then, when the torque signal having the absolute values is filtered using the low pass filter, the filtering-obtained torque signal is shown as indicated by L2 in FIG. 3.

Subsequently, the processor 130 may detect an optimal value for the notch depth of the notch filter 20 that minimizes a function value of an objective function that is defined as a mean squared error between a pre-processed torque signal and a preset target torque signal (S207). In Step S207, the processor 130 may detect the optimal value for the notch depth of the notch filter 20 by executing the steepest gradient descent algorithm with respect to the objective function. A transfer function of the notch filter 20 may be defined as in Mathematical Equation 1 that follows. The processor 130 may detect the optimal value for the notch depth of the notch filter 20 by reiterating a process of updating the notch depth of the notch filter 20 using Mathematical Equation 2 that follows.

$${G}_{fil} ( s ) = \frac{{s}^{2} + \frac{2}{\frac{1}{β} + β} {ζ}_{w} α s + {α}^{2}}{{s}^{2} + {ζ}_{w} α s + {α}^{2}} \qquad Mathematical Equation 1$$

where s depicts a Laplace complex variable, β depicts a notch depth, ζ_{w} depicts a notch width (bandwidth), and a depicts the order of noise and vibration (the order of a noise frequency).

$${γ}_{k + 1} = {γ}_{k} + 2 μ \frac{( 1 - {γ}_{k} ) {ζ}_{w} α s}{{s}^{2} + {ζ}_{w} α s + {α}^{2}} \frac{{ζ}_{w} α s}{{s}^{2} + {ζ}_{w} α s + {α}^{2}} {τ}_{ref}^{2} \qquad Mathematical Equation 2$$

where γ depicts 2/(1/β+β), μ is a step size of a steepest gradient descent algorithm, and τ_{ref} is a torque signal. γ may have a value that is equal to or greater than 0.1, but is equal to or smaller than 0.9. When the steering speed of the steering wheel does not reach the preset reference speed (for example, 0.5 RPS), the processor 130 may change γ to a preset initial value. That is, when the parameter of the notch filter 20 is not possibly optimized, the processor 130 may set the preset initial value to a γ value. In the second embodiment, an amount of computation that is performed during a process of detecting the optimal value for the notch depth of the notch filter 20 may be minimized by substituting γ for

$$\frac{2}{\frac{1}{β} + β} .$$

Mathematical Equation 2 that precedes may be derived by substituting the objective function, defined as in Mathematical Equation 3 that follows, into Equation for the steepest gradient descent algorithm, defined as in Mathematical Equation 4 that follows. In Mathematical Equation 3, τ_{fil} may be a target torque signal.

$$J = {( {τ}_{ref} - {τ}_{fil} )}^{2} = {\{ \frac{( 1 - {γ}_{k} ) {ζ}_{w} α s}{{s}^{2} + {ζ}_{w} α s + {α}^{2}} {τ}_{ref} \}}^{2} \qquad Mathematical Equation 3$$

$${γ}_{k + 1} = {γ}_{k} - μ \frac{\partial J ( {γ}_{k} )}{\partial {γ}_{k}} \qquad Mathematical Equation 4$$

Subsequently, the processor 130 may apply the optimal value for the notch depth of the notch filter 20, detected in Step S207, to the notch filter 20 (S209). That is, the processor 130 may change a setting of the parameter of the notch filter 20 in such a manner that the optimal value detected in Step S207 represents the notch depth of the notch filter 20.

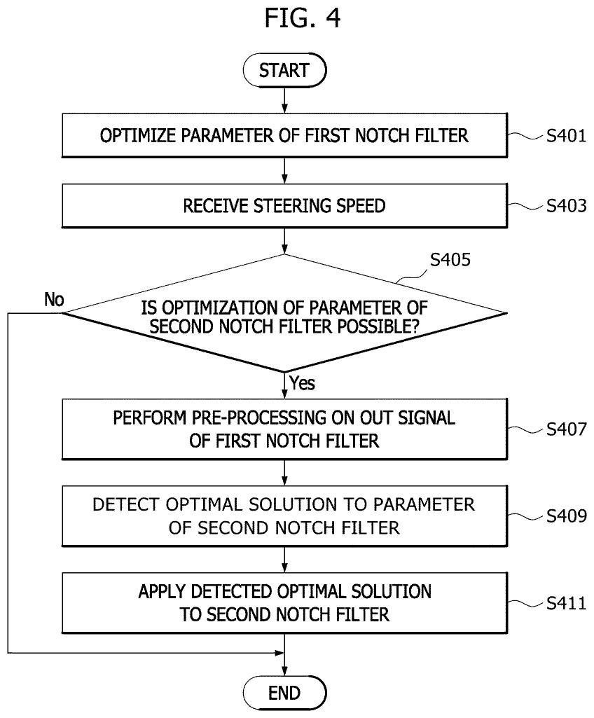

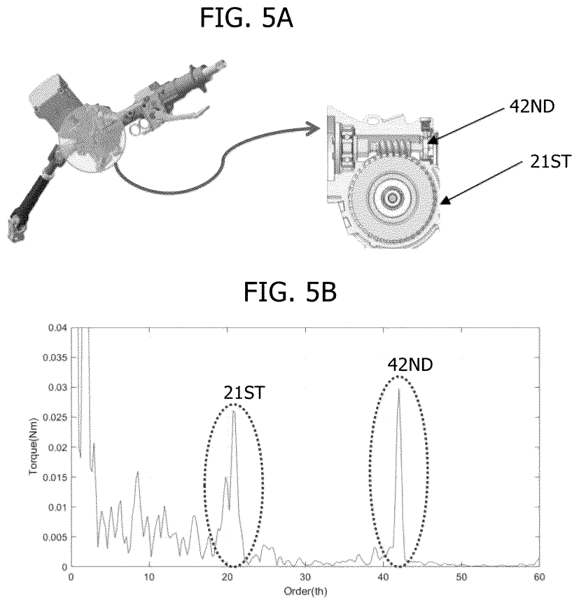

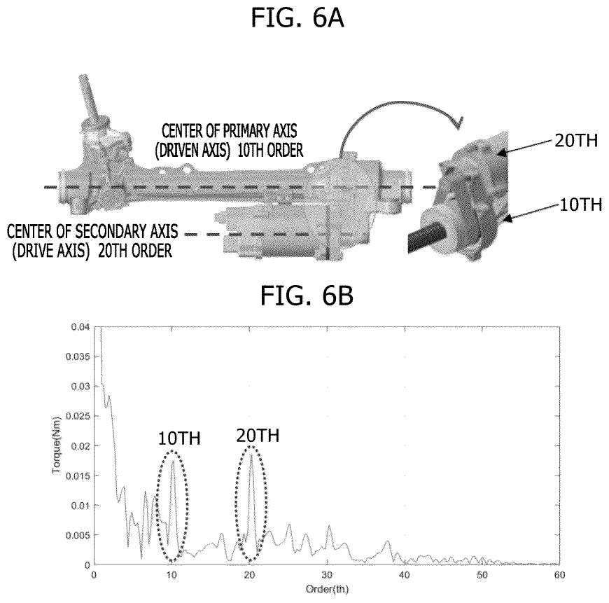

FIG. 4 is a flowchart illustrating a method of optimizing a parameter of a notch filter for use in an electric power steering apparatus according to a third embodiment of the present disclosure. FIG. 5A is a view illustrating a column-electric power steering (C-EPS) apparatus. FIG. 5B is a graph showing the results of analyzing noise and vibration of the column-electric power steering apparatus. FIG. 6A is a view illustrating a rack-electric power steering (R-EPS) apparatus. FIG. 6B is a graph showing the results of analyzing noise and vibration of the rack-electric power steering apparatus.

As illustrated and shown in FIGS. 5A and 5B, when the column-electric power steering (C-EPS) apparatus is in operation, a phenomenon occurs where the torque signal of the steering wheel increases to a predetermined magnitude or higher at the 21st order and the 42nd order. Due to this phenomenon, noise and vibration may occur. Likewise, as illustrated and shown in FIGS. 6A and 6B, when the rack-electric power steering (R-EPS) apparatus is in operation, a phenomenon occurs where the torque signal of the steering wheel increases to a predetermined magnitude or higher at the 10th order and the 20th order. Due to this phenomenon, noise and vibration may occur.

In order to address these problems, a first notch filter for eliminating noise and vibration that correspond to the first order (for example, the 21st order in the case of the C-EPS), and a second notch filter for eliminating noise and vibration that correspond to the second order (for example, the 42nd order in the case of C-EPS) are used in the electric power steering apparatus.

Steps of optimizing parameters of the first and second notch filters in a case where the notch filter 20 is configured with the first and second notch filters are described below with reference to FIG. 4. One or several of steps described below may be performed in a different order from the one described below or may be omitted.

First, the processor 130 may optimize the notch depth of the first notch filter (S401). In Step S401, the processor 130 may optimize the notch depth of the first filter in the same manner as in Steps S201 to S207.

Subsequently, the processor 130 may receive information on the steering speed through the communication interface 110 (S403) and may determine, based on the received information on the steering speed, whether or not the parameter of the second notch filter is possibly optimized (S405). When the steering speed of the steering wheel reaches or exceeds the preset reference speed, the processor 130 may determine that the parameter of the second notch filter is possibly optimized. The reference speed here may be set, taking into consideration factors, such as a step size and characteristics of the second notch filter, that are used when executing the steepest gradient descent algorithm.

When it is determined that the parameter of the second notch filter is possibly optimized, the processor 130 may perform pre-processing on an output signal of the first notch filter (S407). The processor 130 may perform pre-processing on an output of the first notch filter in the same manner as in Step S205 in FIG. 2.

Subsequently, the processor 130 may detect an optimal value for the notch depth of the second notch filter that minimizes a function value of an objective function that is defined as a mean squared error between the pre-processed output signal of the first notch filter and a preset target torque signal (S409). The processor 130 may detect the optimal value for the notch depth of the second notch filter in the same manner as in Step S207 in FIG. 2. The target torque signals for the first notch filter and the second notch filter may also be set to be different from each other.

Subsequently, the processor 130 may apply the optimal value for the notch depth of the second notch filter, detected in Step S409, to the second notch filter (S411). That is, the processor 130 may change the setting of the parameter of the second notch filter in such a manner that the optimal value detected in Step S207 represents the notch depth of the second notch filter.

According to the third embodiment, the parameter of the second notch filter is described above as being optimized after the parameter of the first notch filter is completely optimized. However, the parameter of the second notch filter may be optimized at the same time the parameter of the first notch filter is optimized.

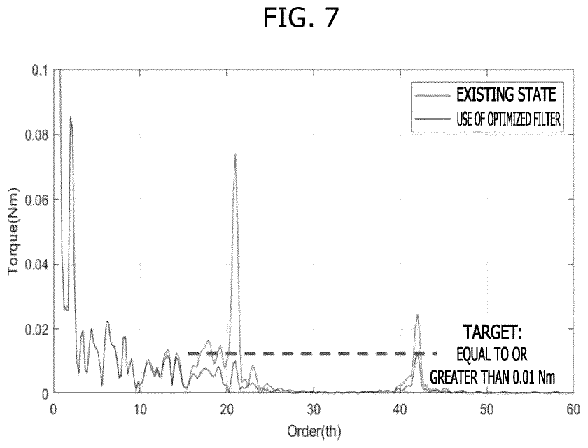

FIG. 7 is a graph showing the performance of the apparatus for optimizing a parameter of a notch filter for use in the electric power steering apparatus according to the first embodiment of the present disclosure.

From FIG. 7, it can be seen that NVH characteristics of the column-electric power steering (C-EPS) are improved in a case where the parameter of the notch filter for use in the column-electric power steering apparatus is optimized according to the first, second, and third embodiments of the present disclosure.

As described above, the apparatus for and the methods of optimizing a parameter of a notch filter for use in the electric power steering apparatus according to the first, second, and third embodiments, respectively, of the present disclosure optimize the parameter of the notch filter for use in the electric power steering apparatus, based on the column torque resulting from the rotation of the steering wheel. Consequently, noise, vibration, and harshness (NVH) characteristics of the electric power steering apparatus can be improved, and the time taken to optimize the parameter of the notch filter 20 can be shortened.

Features of the present disclosure, which are described in the present specification, may be realized in the form of, for example, a method, a process, an apparatus, a software program, a data stream, or a signal. The features, although described in terms of realization in a single form (for example, although described as only a method), may also be implemented in other forms (for example, an apparatus or a program). The apparatus may be implemented in the form of adequate hardware, software, firmware, or the like. The method may be implemented, for example, computers, microprocessors, or devices such as processors that typically refer to processing devices, including integrated circuits, programmable logic devices, and the like. The processors also include those that are used in computers, cellular phones, portable information terminals, personal digital assistants (“PDAS”), and other communication devices that facilitate communication of information between end users.

The embodiments of the present disclosure are described only in an exemplary manner with reference to the drawings. From the description of the embodiments, it would be apparent to a person of ordinary skill in the art to which the present disclosure pertains that various modifications are possibly made to the embodiments and that other embodiments equivalent thereto are possibly practiced. Therefore, the proper technical scope of the present disclosure should be defined in the following claims.

What is claimed is:

1. An apparatus for optimizing a parameter of a notch filter for use in an electric power steering apparatus to eliminate noise and vibration occurring in the electric power steering apparatus, the apparatus comprises:
a communication interface; and
a processor operatively connected to the communication interface,
wherein the processor is configured to:
receive, through the communication interface operatively connected to a torque sensor, a torque signal from the torque sensor detecting column torque resulting from rotation of a steering wheel,
detect an optimal value for a notch depth of the notch filter that minimizes a function value of an objective function that is defined as a mean squared error between the torque signal and a preset target torque signal of the notch filter, and
apply the optimal value to the notch filter operatively connected to the processor.

2. The apparatus of claim 1, wherein the processor detects the optimal value for the notch depth by executing a steepest gradient descent algorithm with respect to the objective function.

3. The apparatus of claim 2, wherein the processor detects the optimal value for the notch depth by reiterating a process of updating the notch depth using Mathematical Equation that follows, until the notch depth converges:
$${γ}_{k + 1} = {γ}_{k} + 2 μ \frac{( 1 - {γ}_{k} ) {ζ}_{w} α s}{{s}^{2} + {ζ}_{w} α s + {α}^{2}} \frac{{ζ}_{w} α s}{{s}^{2} + {ζ}_{w} α s + {α}^{2}} {τ}_{ref}^{2}$$
where γ depicts 2/(1/β+β), β depicts a notch depth, μ depicts a step size of a steepest gradient descent algorithm, ζ_{w} depicts a notch width (bandwidth), α depicts the order of noise and vibration (the order of a noise frequency), s depicts a Laplace complex variable, and τ_{ref} depicts a torque signal.

4. The apparatus of claim 1, wherein the processor determines whether or not the notch depth is possibly optimized, and in response that the notch depth is determined to be optimized, the processor detects the optimal value.

5. The apparatus of claim 4, wherein the processor receives information on a steering speed of the steering wheel through the communication interface, and, in response that the steering speed reaches or exceeds a preset reference speed, the processor concludes that the notch depth is possibly optimized.

6. The apparatus of claim 1, wherein the processor filters the torque signal using a band pass filter, converts the filtered torque signal into a torque signal having absolute values, filters the torque signal having the absolute values, using a low pass filter, and thus pre-processes the torque signal.

7. The apparatus of claim 1, wherein the notch filter is a secondary notch filter of which an input is an output of a different notch filter, and the processor detects the optimal value for the notch depth of the notch filter using an objective function that is defined a mean squared error between an output signal of the different notch filter and the preset target torque signal, and applies the optimal value to the notch filter.

8. A method of optimizing a parameter of a notch filter for use in an electric power steering apparatus to eliminate noise and vibration occurring in the electric power steering apparatus, the method comprises:
receiving, by a processor operatively connected to the notch filter and a torque sensor, through a communication interface operatively connected to the processor, a torque signal from the torque sensor detecting column torque resulting from rotation of a steering wheel;
detecting, by the processor, an optimal value for a notch depth of the notch filter that minimizes a function value of an objective function that is defined as a mean squared error between the torque signal and a preset target torque signal of the notch filter; and
applying, by the processor, the optimal value to the notch filter.

9. The method of claim 8, wherein in the detecting of the optimal value for the notch depth of the notch filter, the optimal value for the notch depth is detected by executing a steepest gradient descent algorithm with respect to the objective function.

10. The method of claim 9, wherein in the detecting of the optimal value for the notch depth of the notch filter, the optimal value for the notch depth is detected by reiterating a process of updating the notch depth using Mathematical Equation that follows, until the notch depth converges:
$${γ}_{k + 1} = {γ}_{k} + 2 μ \frac{( 1 - {γ}_{k} ) {ζ}_{w} α s}{{s}^{2} + {ζ}_{w} α s + {α}^{2}} \frac{{ζ}_{w} α s}{{s}^{2} + {ζ}_{w} α s + {α}^{2}} {τ}_{ref}^{2}$$
where γ depicts 2/(1/β+β), β depicts a notch depth, μ depicts a step size of a steepest gradient descent algorithm, ζ_{w} depicts a notch width (bandwidth), α depicts the order of noise and vibration (the order of a noise frequency), s depicts a Laplace complex variable, and τ_{ref} depicts a torque signal.

11. The method of claim 8, wherein the processor determines whether or not the notch depth is possibly optimized, and in response that the notch depth is determined to be optimized, the processor detects the optimal value.

12. The method of claim 11, wherein the processor receives information on a steering speed of the steering wheel through the communication interface, and, in response that the steering speed reaches or exceeds a preset reference speed, the processor concludes that the notch depth is possibly optimized.

13. The method of claim 8, wherein the processor filters the torque signal using a band pass filter, converts the filtered torque signal into a torque signal having absolute values, filters the torque signal having the absolute values, using a low pass filter, and thus pre-processes the torque signal.

14. The method of claim 8, wherein the notch filter is a secondary notch filter of which an input is an output of a different notch filter, and the processor detects the optimal value for the notch depth of the notch filter using an objective function that is defined a mean squared error between an output signal of the different notch filter and the preset target torque signal, and applies the optimal value to the notch filter.

15. A non-transitory computer readable storage medium on which a program for performing the method of claim 8, is recorded.
